(19) United States
(12) Patent Application Publication
(10) Pub. No.: US 2026/0293153 A1
(43) Pub. Date: Sep. 24, 2026

(54) MAGNETIC MEMORY DEVICE AND METHOD OF MANUFACTURING THE MAGNETIC MEMORY DEVICE

(71) Applicant: Kioxia Corporation, Tokyo (JP)

(72) Inventor: Yuuichi KAMIMUTA, Seoul (KR)

(73) Assignee: Kioxia Corporation, Tokyo (JP)

(21) Appl. No.: 19/325,912

(22) Filed: Sep. 11, 2025

(30) Foreign Application Priority Data
Mar. 19, 2025 (JP) 2025-045713

(51) Int. Cl. H10B 61/00; H10N 50/01; H10N 50/10

(52) U.S. Cl. CPC H10B 61/10; H10N 50/01; H10N 50/10

(57) ABSTRACT

According to one embodiment, a magnetic memory device includes a selector body, a MTJ body provided above the selector body, and an electrode provided between the selector body and the MTJ body. The electrode includes a first sub-electrode having a first conductor and a second conductor which is positioned closer to the MTJ body than the first conductor and is in contact with the first conductor. The first conductor has a crystal structure. The second conductor has an amorphous structure.

### CROSS-REFERENCE TO RELATED APPLICATIONS

This application is based upon and claims the benefit of priority from Japanese Patent Application No. 2025-045713, filed Mar. 19, 2025, the entire contents of which are incorporated herein by reference.

### FIELD

Embodiments described herein relate generally to a magnetic memory device and a method of manufacturing the magnetic memory device.

### BACKGROUND

A magnetic memory device (magnetoresistive random access memory (MRAM)) using a magnetoresistance effect element as a memory element is known. The magnetoresistance effect element is connected in series with a switching element and functions as a memory cell.

### BRIEF DESCRIPTION OF THE DRAWINGS

FIG. 1 is a block diagram showing an example of a configuration of a magnetic memory device according to a first embodiment.

FIG. 2 is a circuit diagram showing an example of a circuit configuration of a memory cell array included in the magnetic memory device according to the first embodiment.

FIG. 3 is a perspective view showing an example of a three-dimensional structure of the memory cell array included in the magnetic memory device according to the first embodiment.

FIG. 4 is a cross-sectional view taken along line IV-IV of FIG. 3, showing an example of a cross-sectional structure of the memory cell array included in the magnetic memory device according to the first embodiment.

FIG. 5 is a cross-sectional view taken along line V-V of FIG. 3, showing an example of a cross-sectional structure of the memory cell array included in the magnetic memory device according to the first embodiment.

FIG. 6 is a cross-sectional view showing an example of a cross-sectional structure of a magnetoresistance effect element included in the magnetic memory device according to the first embodiment.

FIG. 7 is a flowchart showing an example of a method of manufacturing the memory cell array in the magnetic memory device according to the first embodiment.

FIG. 8 is a cross-sectional view for illustrating an example of the method of manufacturing the memory cell array in the magnetic memory device according to the first embodiment.

FIG. 9 is a cross-sectional view for illustrating an example of the method of manufacturing the memory cell array in the magnetic memory device according to the first embodiment.

FIG. 10 is a cross-sectional view for illustrating an example of the method of manufacturing the memory cell array in the magnetic memory device according to the first embodiment.

FIG. 11 is a cross-sectional view for illustrating an example of the method of manufacturing the memory cell array in the magnetic memory device according to the first embodiment.

FIG. 12 is a cross-sectional view for illustrating an example of the method of manufacturing the memory cell array in the magnetic memory device according to the first embodiment.

FIG. 13 is a cross-sectional view for illustrating an example of the method of manufacturing the memory cell array in the magnetic memory device according to the first embodiment.

FIG. 14 is a cross-sectional view for illustrating an example of the method of manufacturing the memory cell array in the magnetic memory device according to the first embodiment.

FIG. 15 is a cross-sectional view for illustrating an example of the method of manufacturing the memory cell array in the magnetic memory device according to the first embodiment.

FIG. 16 is a cross-sectional view for illustrating a step of exposing an upper surface of a middle electrode in a method of manufacturing a memory cell array in a magnetic memory device according to a comparative example.

FIG. 17 is a cross-sectional view taken along line IV-IV of FIG. 3, showing an example of a cross-sectional structure of a memory cell array included in a magnetic memory device according to a second embodiment.

FIG. 18 is a cross-sectional view taken along line V-V of FIG. 3, showing an example of a cross-sectional structure of the memory cell array included in the magnetic memory device according to the second embodiment.

FIG. 19 is a flowchart showing an example of a method of manufacturing the memory cell array in the magnetic memory device according to the second embodiment.

FIG. 20 is a cross-sectional view for illustrating an example of the method of manufacturing the memory cell array in the magnetic memory device according to the second embodiment.

FIG. 21 is a cross-sectional view for illustrating an example of the method of manufacturing the memory cell array in the magnetic memory device according to the second embodiment.

FIG. 22 is a cross-sectional view for illustrating an example of the method of manufacturing the memory cell array in the magnetic memory device according to the second embodiment.

FIG. 23 is a cross-sectional view for illustrating an example of the method of manufacturing the memory cell array in the magnetic memory device according to the second embodiment.

FIG. 24 is a cross-sectional view for illustrating an example of the method of manufacturing the memory cell array in the magnetic memory device according to the second embodiment.

FIG. 25 is a cross-sectional view for illustrating an example of the method of manufacturing the memory cell array in the magnetic memory device according to the second embodiment.

FIG. 26 is a cross-sectional view for illustrating an example of the method of manufacturing the memory cell array in the magnetic memory device according to the second embodiment.

### DETAILED DESCRIPTION

In general, according to one embodiment, a magnetic memory device includes a selector body, an MTJ body provided above the selector body, and an electrode provided between the selector body and the MTJ body. The electrode includes a first sub-electrode having a first conductor and a second conductor which is positioned closer to the MTJ body than the first conductor and is in contact with the first conductor. The first conductor has a crystal structure. The second conductor has an amorphous structure.

Hereinafter, embodiments will be described with reference to the accompanying drawings. Each embodiment will exemplify a device and a method for embodying the technical idea of the invention. The drawings are schematic or conceptual. The dimensions, ratios, etc., in the drawings are not always the same as the actual ones. Parts of the configurations may be suitably omitted. The hatching applied in the planar views does not necessarily relate to the material or characteristics of the hatched components. Throughout the specification, constituent elements having substantially the same function and configuration will be assigned the same reference symbol. The reference symbols may include numerals or character strings to distinguish similar components having the same reference symbols from each other. Throughout the specification, “a stacked film including A/B” indicates a stacked structure of a film including element A and a film including element B.

### 1. First Embodiment

A magnetic memory device according to a first embodiment will be described. Examples of the magnetic memory device according to the first embodiment include a magnetic memory device of a perpendicular magnetic recording type which uses, as a resistance change element, an element that exhibits a magnetoresistance effect through a magnetic tunnel junction (MTJ). In the following description, such a resistance change element may also be referred to as a “magnetoresistance effect element MTJ”.

### 1.1 Configuration

First, a configuration of a magnetic memory device according to the first embodiment will be described.

### 1.1.1 Configuration of Magnetic Memory Device

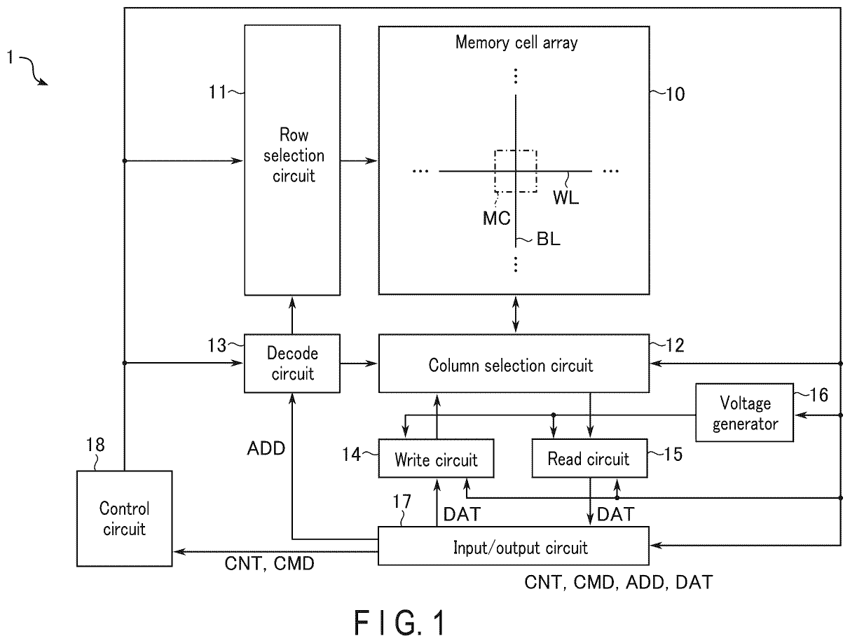

FIG. 1 is a block diagram showing an example of a configuration of the magnetic memory device according to the first embodiment. As illustrated in FIG. 1, the magnetic memory device 1 includes a memory cell array 10, a row selection circuit 11, a column selection circuit 12, a decode circuit 13, a write circuit 14, a read circuit 15, a voltage generator 16, an input/output circuit 17, and a control circuit 18.

The memory cell array 10 includes a plurality of memory cells MC each associated with a pair of a row and a column. The memory cells MC arranged in the same row are coupled to the same word line WL. The memory cells MC arranged in the same column are coupled to the same bit line BL.

The row selection circuit 11 is coupled to the memory cell array 10 via word lines WL. The row selection circuit 11 is supplied with a decoding result (row address) of an address ADD received from the decode circuit 13. The row selection circuit 11 sets a word line WL corresponding to the row based on the decoding result of the address ADD to a selected state.

The column selection circuit 12 is coupled to the memory cell array 10 via the bit lines BL. The column selection circuit 12 is supplied with a decoding result (column address) of an address ADD received from the decode circuit 13. The column selection circuit 12 sets a bit line BL corresponding to a column based on the decoding result of the address ADD, to a selected state.

The decode circuit 13 decodes the address ADD received from the input/output circuit 17. The decode circuit 13 supplies a decoding result of the address ADD to the row selection circuit 11 and the column selection circuit 12. The address ADD includes a row address and a column address which are to be selected.

The write circuit 14 writes data to each memory cell MC. The write circuit 14 includes, for example, a write driver (not shown).

The read circuit 15 reads data from the memory cells MC. The read circuit 15 includes, for example, a sense amplifier (not shown).

The voltage generator 16 generates voltages for various types of operations of the memory cell array 10, using a power supply voltage provided from external equipment (not shown) of the magnetic memory device 1. For example, the voltage generator 16 generates various voltages required for a write operation, and outputs them to the write circuit 14. For example, the voltage generator 16 generates various voltages required for a read operation, and outputs them to the read circuit 15.

The input/output circuit 17 governs communications with the outside of the magnetic memory device 1. The input/output circuit 17 transfers an address ADD received from the outside of the magnetic memory device 1 to the decode circuit 13. The input/output circuit 17 also transfers a control signal CNT and a command CMD received from the outside of the magnetic memory device 1 to the control circuit 18. The input/output circuit 17 transfers data DAT received from the outside of the magnetic memory device 1 to the write circuit 14, and outputs to the outside of the magnetic memory device 1 the data DAT transferred from the read circuit 15.

The control circuit 18 controls, based on control signals CNT and commands CMD, the operations of the row selection circuit 11, the column selection circuit 12, the decode circuit 13, the write circuit 14, the read circuit 15, the voltage generator 16, and the input/output circuit 17 that are included in the magnetic memory device 1.

### 1.1.2 Configuration of Memory Cell Array

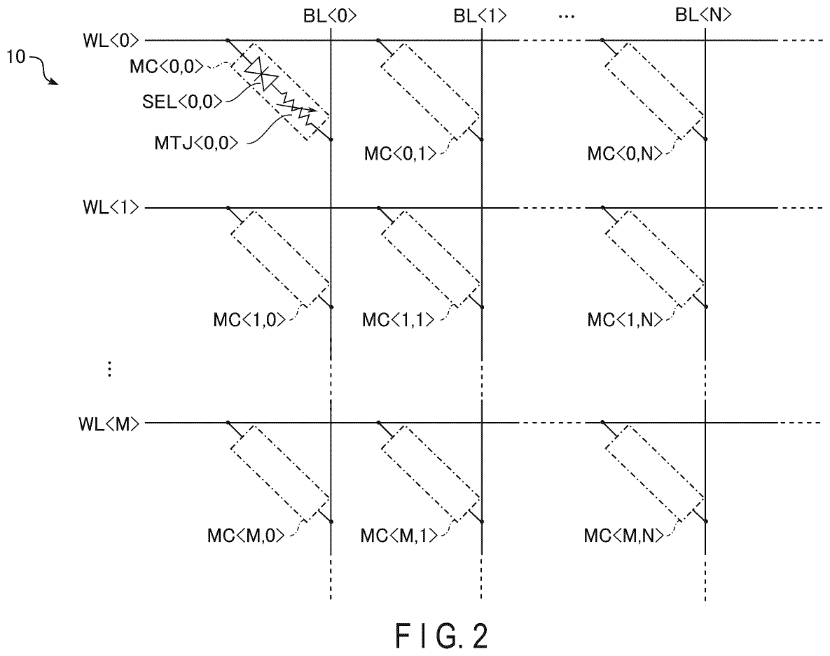

Next, a configuration of the memory cell array 10 in the magnetic memory device 1 according to the first embodiment will be described with reference to FIG. 2. FIG. 2 is a circuit diagram showing an example of a circuit configuration of the memory cell array 10 included in the magnetic memory device 1 according to the first embodiment. In FIG. 2, the word lines WL and the bit lines BL are distinguished by appended letters including indices (“<>”).

As illustrated in FIG. 2, the memory cells MC are arranged in a matrix in the memory cell array 10, and each memory cell MC is associated with a pair of one of the bit lines BL (BL<0>, BL<1>, . . . , BL<N>) and one of the word lines WL (WL<0>, WL<1>, . . . , WL<M>) (where M and N are natural numbers). That is, a memory cell MC<i, j> (0≤i≤M, 0≤j≤N) is coupled between a word line WL<i> and a bit line BL<j>.

The memory cell MC<i, j> includes a switching element SEL<i, j> and a magnetoresistance effect element MTJ<i, j> coupled in series.

A switching element SEL is a 2-terminal type switching element. A 2-terminal type switching element differs from a 3-terminal type switching element, such as a transistor, etc., in that the former does not have a third terminal. In a case where a voltage applied between two terminals is smaller than a threshold voltage Vth (a voltage applied between two terminals<the threshold voltage Vth), the switching element SEL is in a high-resistance state. Such a high-resistance state is, for example, an “OFF” state which indicates an electrically non-conductive state. In a case where a voltage applied between two terminals is equal to or greater than the threshold voltage Vth (a voltage applied between two terminals≥the threshold voltage Vth), the switching element SEL is in a low-resistance state. Such a low-resistance state is an “ON” state which indicates an electrically conductive state. More specifically, for example, in a case where a voltage applied to a corresponding memory cell is smaller than the threshold voltage Vth (a voltage applied to a corresponding memory cell MC<the threshold voltage Vth), the switching element SEL serves as an insulator having a great resistance value and interrupts a current. That is, the switching element SEL enters the OFF state. In a case where a voltage applied to a corresponding memory cell is equal to or greater than the threshold voltage Vth (a voltage applied to a corresponding memory cell MC≥the threshold voltage Vth), the switching element SEL serves as a conductor having a small resistance value and allows a current to pass therethrough. That is, the switching element SEL enters the ON state. The switching element SEL switches between allowing a current to pass and interrupting such a current, in accordance with a magnitude of a voltage applied to a corresponding memory cell MC, regardless of the polarity of the voltage applied to the two terminals (regardless of the direction of the current passing between the terminals). In the following description, the switching element SEL will also be referred to as a “selector body”.

With a current controlled by the switching element SEL, the magnetoresistance effect element MTJ enters the low-resistance state or the high-resistance state. That is, with a current controlled by the switching element SEL, a resistance state of the magnetoresistance effect element MTJ can be switched between the low-resistance state and the high-resistance state. The magnetoresistance effect element MTJ functions as a memory element that allows data to be written therein according to a change in its resistance state, retains the written data in a non-volatile manner, and allows the retained data to be read therefrom. In the following description, the magnetoresistance effect element MTJ will also be referred to as an “MTJ body”.

### 1.1.3 Structure of Memory Cell Array

Next, a structure of the memory cell array 10 in the magnetic memory device 1 according to the first embodiment will be described. The following description will use an xyz orthogonal coordinate system. An X direction corresponds to an extending direction of the word line WL. A Y direction corresponds to an extending direction of the bit line BL. A Z direction corresponds to a direction vertical to a surface of a semiconductor substrate for use in formation of the magnetic memory device 1. The term “low” and its derivative and relevant terms refer to a position at a smaller coordinate on the z axis. The term “up” and its derivative and relevant terms refer to a position at a larger coordinate on the z axis. In the perspective views, hatching is added where appropriate. The hatching added to the perspective views is not necessarily related to the materials or characteristics of the hatched constituent elements. The perspective view and the cross-sectional view omit illustration of configurations such as an interlayer insulating layer.

### 1.1.3.1 Three-Dimensional Structure of Memory Cell Array

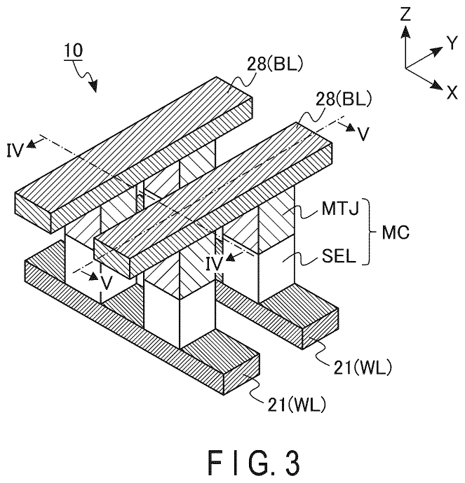

An example of a three-dimensional structure of the memory cell array 10 will be described with reference to FIG. 3. FIG. 3 is a perspective view showing an example of a three-dimensional structure of the memory cell array 10 included in the magnetic memory device 1 according to the first embodiment.

The memory cell array 10 is provided above a semiconductor substrate (not shown).

As shown in FIG. 3, the memory cell array 10 includes a plurality of conductors (interconnects) 21, a plurality of conductors (interconnects) 28, and the plurality of memory cells MC.

The plurality of conductors 28 are provided above the plurality of conductors 21.

The plurality of conductors 21 each have a portion extending in an X direction. The plurality of conductors 21 are aligned in a Y direction and are apart from each other. The conductors 21 are each used as the word line WL.

The conductors 28 each have a portion extending in the Y direction. The plurality of conductors 28 are aligned in the X direction and are apart from each other. The conductors 28 are each used as the bit line BL.

The conductors 21 and the conductors 28 are spaced apart from each other in the Z direction. One memory cell MC is provided at each of the intersections between the conductors 21 and the conductors 28. In other words, each memory cell MC is formed into a columnar shape between its associated word line WL and bit line BL. The memory cell MC has a structure in which the switching element SEL is provided below the magnetoresistance effect element MTJ, for example.

Meanwhile, the memory cell array 10 may have a structure in which the conductors 28, the memory cells MC, and the conductors 21 are stacked in this order.

### 1.1.3.2 Cross-Sectional Structure of Memory Cell Array

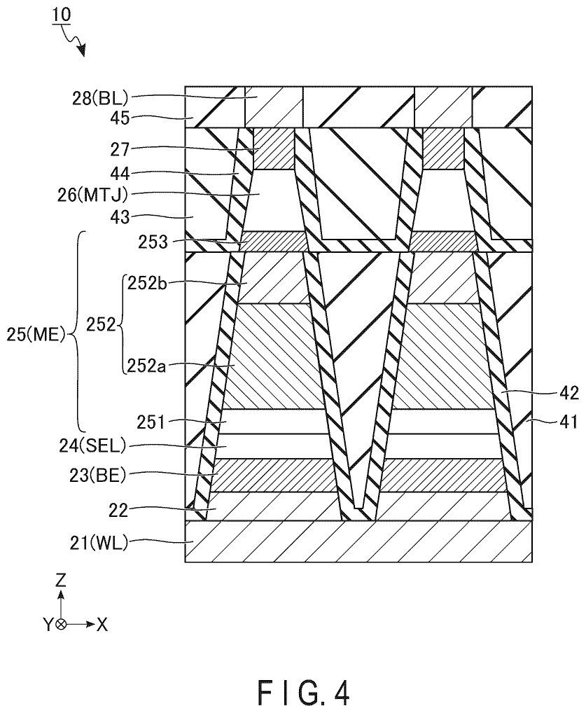

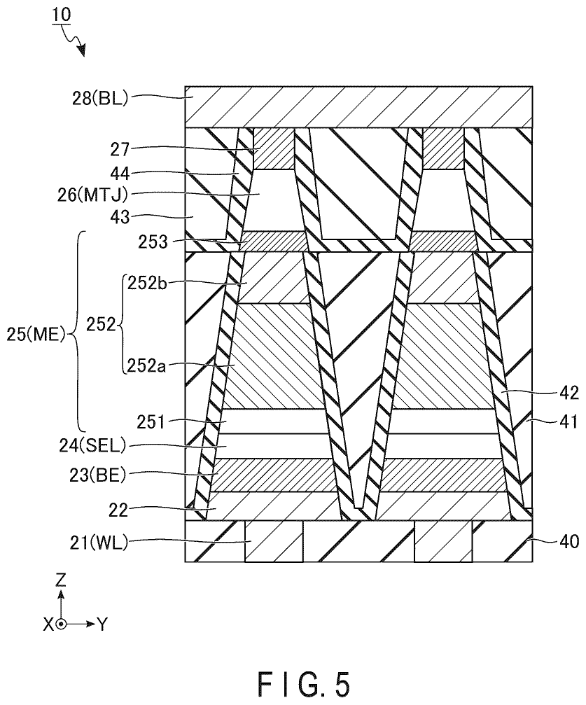

An example of the cross-sectional structure of the memory cell array 10 will be described with reference to FIG. 4 and FIG. 5. FIG. 4 is a cross-sectional view taken along line IV-IV of FIG. 3, showing an example of a cross-sectional structure of the memory cell array 10 included in the magnetic memory device 1 according to the first embodiment. FIG. 5 is a cross-sectional view taken along line V-V of FIG. 3, showing an example of a cross-sectional structure of the memory cell array 10 included in the magnetic memory device 1 according to the first embodiment.

As shown in FIG. 4 and FIG. 5, the memory cell array 10 includes the plurality of conductors 21, a plurality of conductors 22, a plurality of electrode 23, a plurality of selector bodies 24, a plurality of electrodes 25, a plurality of MTJ bodies 26, a plurality of conductors 27, the plurality of conductors 28, and insulators 40 to 45.

For example, the plurality of conductors 21 are provided above the semiconductor substrate (not shown). The plurality of conductors 21 are aligned in the Y direction. The plurality of conductors 21 each extend in the X direction. The plurality of conductors 21 each have conductivity and function as the word line WL.

The insulator 40 is provided in each region between two conductors 21 that are adjacent to each other in the Y direction. In this manner, the plurality of conductors 21 are insulated from each other. The insulator 40 is formed of an insulating material and includes, for example, silicon oxide (SiO₂) and silicon nitride (SiN). The insulator 40 may be formed of a plurality of insulating materials.

Meanwhile, the plurality of conductors 21 and the insulator 40 may be provided on an upper surface of the semiconductor substrate or may be provided apart from the semiconductor substrate without being in contact therewith.

The plurality of conductors 22 are provided on an upper surface of each of the plurality of conductors 21. The plurality of conductors 22 provided on the upper surface of the same conductor 21 are aligned in the X direction. The plurality of conductors 22 each have conductivity. A combination of a single conductor 21 and a plurality of conductors 22 provided on the upper surface of the conductor 21 will be referred to as a “word line WL”.

On an upper surface of each of the plurality of conductors 22, a corresponding one of the plurality of electrodes 23 is provided. The plurality electrodes 23 each have conductivity and function as a lower electrode BE.

On an upper surface of each of the plurality of electrodes 23, a corresponding one of the plurality of selector bodies 24 is provided. The plurality of selector bodies 24 each function as a switching element SEL.

On an upper surface of each of the plurality of selector bodies 24, a corresponding one of the plurality of electrodes 25 is provided. The plurality of electrodes 25 each function as a middle electrode ME.

The plurality of electrodes 25 each include conductors 251, 252, and 253. In the following description, the conductor 251 will also be referred to as a “sub-electrode 251”. The conductor 252 will also be referred to as a “sub-electrode 252”. The conductor 253 will also be referred to as a “sub-electrode 253”.

The sub-electrode 251 is provided on the upper surface of the selector body 24. The sub-electrode 251 is provided to improve the characteristics of the selector body 24. The sub-electrode 251 is formed of a conductive material and includes at least one element or compound selected from, for example, carbon (C) and carbon nitride (CN). The sub-electrode 251 has, for example, an amorphous structure. The sub-electrode 251 has a thickness of, for example, 2 nanometers (nm) or greater and 20 nanometers (nm) or smaller. With the thickness within the range described above, the sub-electrode 251 can be prevented from peeling off the upper surface of the selector body 24.

The sub-electrode 252 is provided on an upper surface of sub-electrode 251. The sub-electrodes 252 includes conductors 252a and 252b. The sub-electrode 252 has a thickness of, for example, 20 nanometers (nm) or greater and 50 nanometers (nm) or smaller.

The conductor 252a is provided on the upper surface of the sub-electrode 251. The conductor 252b is provided on an upper surface of the conductor 252a. In other words, the conductor 252b is positioned closer to the MTJ body 26 than the conductor 252a and is in contact with the conductor 252a. The conductor 252b is provided to secure flatness of the electrode 25 (middle electrode ME).

The conductors 252a and 252b are each formed from a conductive material. The conductors 252a and 252b include at least one element or compound selected from, for example, a high-melting-point metal element and a compound thereof. In the present embodiment, a high-melting-point metal is a material having a melting point higher than that of iron (Fe) and cobalt (Co), for example. Such a conductive material includes at least one element or compound selected from, for example, titanium (Ti), tantalum (Ta), tungsten (W), titanium nitride (TiN), tantalum nitride (TaN), and tungsten nitride (WN). Furthermore, the conductor 252b includes an impurity. For the electrode 25 to function as an electrode, as an impurity included in the conductor 252b, a material that allows the conductor 252b to have conductivity while including such an impurity is used. Such an impurity includes at least one element or compound selected from, for example, aluminum (Al), silicon (Si), boron (B), and carbon (C). As described above, the conductor 252b includes a compound of the aforementioned conductive material and the aforementioned impurity, and has conductivity. The aforementioned conductive material and the aforementioned impurity used for the conductor 252b are combined as appropriate.

Meanwhile, the conductor 252a and the conductor 252b may include impurities such as an element included in a gas used in manufacturing steps of the magnetic memory device 1, or an element mixed into the portion described above from the periphery of the portion. The conductor 252b may include impurities different from the impurities described above.

The conductor 252a has a crystal structure. The conductor 252 a has a thickness of, for example, 10 nanometers (nm) or greater and 40 nanometers (nm) or smaller.

The conductor 252b including the above impurity has an amorphous structure. As will be described later, an upper surface of the conductor 252b is greater in flatness than that in a crystal structure in which the upper surface is formed into a downwardly convex shape through an etch-back process. Generally, as the concentration of impurity included in a conductor increases, the resistance of the conductor concerned increases. The conductor 252b includes the impurity described above, so that the resistance of the conductor 252b is higher than that of the conductor 252a. Furthermore, as the thickness of the conductor 252b increases, the resistance of the conductor 252b increases. Therefore, as the thickness of the conductor 252b in the sub-electrode 252 increases, the resistance of the sub-electrode 252 increases so that the resistance of the electrode 25 also increases. The lower the resistance the electrode 25 has, the more preferable it is. For this reason, the thickness of the conductor 252b is set to be smaller than that of the conductor 252a. The thickness of the conductor 252b is set such that the flatness of the upper surface of the conductor 252b can be ensured by etch-back to be described later. The conductor 252b has a thickness of, for example, 10 nanometers (nm).

The sub-electrode 253 is provided on an upper surface of the sub-electrode 252 and an upper surface of the insulator 42. The sub-electrode 253 is formed of a conductive material and includes least one element or compound selected from, for example, titanium (Ti), tantalum (Ta), tungsten (W), titanium nitride (TiN), tantalum nitride (TaN), and tungsten nitride (WN). The sub-electrode 253 has, for example, a crystal structure.

Meanwhile, the electrode 25 (middle electrode ME) is not limited to the structure shown in FIG. 4 and FIG. 5. For example, the electrode 25 may include another layer or other layers. Furthermore, as long as the characteristics of the selector body 24 can be sufficiently secured, the electrode 25 does not need to include the sub-electrode 251. As long as the flatness of the electrode 25 can be sufficiently secured by the conductor 252b, the electrode 25 does not need to include the sub-electrode 253.

In the following description, the structure including the conductor 22, the electrode 23, the selector body 24, the sub-electrode 251, and the sub-electrode 252 will be referred to as a “first layer stack”. The memory cell array 10 includes a plurality of first layer stacks. A side surface of each of the plurality of first layer stacks is provided with the insulator 42 in such a manner that the side surface concerned is covered with the insulator 42. That is, a side surface of the conductor 22, a side surface of the electrode 23, a side surface of the selector body 24, a side surface of the sub-electrode 251, and a side surface of the sub-electrode 252 are covered with the insulator 42. The insulator 42 is provided in a range from, for example, a position of the upper surface of the conductor 21 to a position of the upper surface of the sub-electrode 252. Furthermore, between two first layer stacks which are adjacent to each other in the X direction or Y direction, the insulator 42 is also provided on the upper surface of the conductor 21 and an upper surface of the insulator 40. The insulator 42 is formed of an insulating material and includes, for example, silicon nitride. The insulator 42 may be formed of a plurality of insulating materials.

The insulator 41 is provided on an upper surface of the insulator 42. The insulator 41 is embedded in a range from a position of the upper surface of the insulator 42 provided on the upper surface of the conductor 21 to a position of the upper surface of the sub-electrode 252, for example. The insulator 41 is formed of an insulating material and includes, for example, silicon oxide and silicon nitride. The insulator 41 may be formed of a plurality of insulating materials.

On an upper surface of each of the plurality of sub-electrodes 253 (plurality of electrodes 25), a corresponding one of the plurality of MTJ bodies 26 is provided. The plurality of MTJ bodies 26 each function as a magnetoresistance effect element MTJ. The configuration of the MTJ bodies 26 will be described later in detail.

On an upper surface of each of the plurality of MTJ bodies 26, a corresponding one of the plurality of conductors 27 is provided. The plurality of conductors 27 each function as a hard mask for use in processing the sub-electrode 253 and the MTJ body 26. The conductor 27 is formed of a conductive material and includes at least one element or compound selected from, for example, titanium (Ti), tantalum (Ta), tungsten (W), titanium nitride (TiN), tantalum nitride (TaN), and tungsten nitride (WN).

In the following description, the structure including the sub-electrode 253, the MTJ body 26, and the conductor 27 will be referred to as a “second layer stack”. The memory cell array 10 includes a plurality of second layer stacks. A side surface of each of the plurality of second layer stacks is provided with the insulator 44 such that the side surface concerned is covered with the insulator 44. That is, a side surface of the sub-electrode 253, a side surface of the MTJ body 26, and a side surface of the conductor 27 are covered with the insulator 44. The insulator 44 is provided in a range from, for example, a position of an upper surface of the insulator 41 to a position of an upper surface of the conductor 27. Furthermore, between two second layer stacks which are adjacent to each other in the X direction or Y direction, the insulator 44 is also provided on the upper surface of the insulator 41 and the upper surface of the insulator 42. The insulator 44 is formed of an insulating material and includes, for example, silicon nitride. The insulator 44 may be formed of a plurality of insulating materials.

The insulator 43 is provided on an upper surface of the insulator 44. The insulator 43 is embedded in a range from a position of the upper surface of the insulator 44 provided on the upper surface of the insulator 41 to a position of the upper surface of the conductor 27. The insulator 43 is formed of an insulating material and includes, for example, silicon oxide and silicon nitride. The insulator 43 may be formed of a plurality of insulating materials.

A single conductor 28 is provided so as to be in contact with an upper surface of each of the plurality of conductors 27 aligned in the Y direction. The plurality of conductors 28 are aligned in the X direction. The plurality of conductors 28 each extend in the Y direction. The plurality of conductors 28 each have conductivity and function as a bit line BL.

The insulator 45 is provided in each region between two conductors 28 that are adjacent to each other in the X direction. In this manner, the plurality of conductors 28 are insulated from each other. The insulator 45 is formed of an insulating material and includes, for example, silicon oxide or silicon nitride. The insulator 45 may be formed of a plurality of insulating materials.

### 1.1.4 Cross-Sectional Structure of Magnetoresistance Effect Element

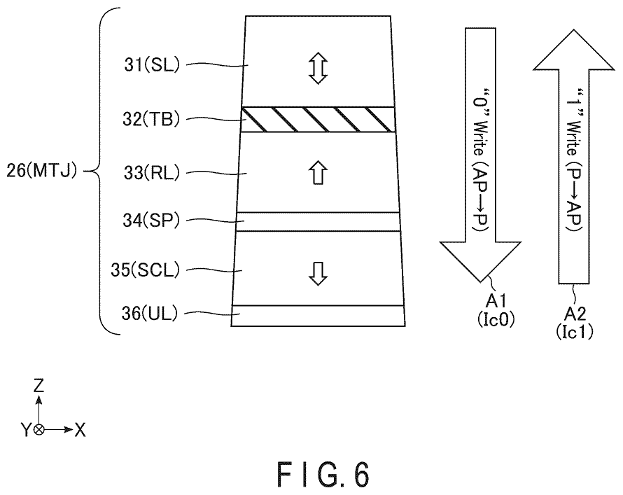

Next, an example of the magnetoresistance effect element MTJ of the magnetic memory device 1 according to the first embodiment, that is, an example of a cross-sectional structure of the MTJ body, will be described with reference to FIG. 6. FIG. 6 is a cross-sectional view showing an example of a cross-sectional structure of the magnetoresistance effect element MTJ included in the magnetic memory device 1 according to the first embodiment.

The MTJ body 26 to be used as the magnetoresistance effect element MTJ includes a ferromagnet 31, a nonmagnet 32, a ferromagnet 33, a nonmagnet 34, a ferromagnet 35, and a nonmagnet 36.

The ferromagnet 31 is a conductive film having ferromagnetic properties. The ferromagnet 31 has a direction of an easy axis of magnetization in a direction (Z direction) perpendicular to the film surface. The ferromagnet 31 includes iron (Fe). The ferromagnet 31 may further include at least one element of cobalt (Co) and nickel (Ni). In addition, the ferromagnet 31 may further include boron (B). More specifically, the ferromagnet 31 may include, for example, cobalt-iron-boron (CoFeB), iron boride (FeB), or cobalt boride (CoB). The ferromagnet 31 is used as a storage layer SL.

The nonmagnet 32 is provided on the lower surface of the ferromagnet 31. The nonmagnet 32 is an insulating film having nonmagnetic properties. The nonmagnet 32 is used as a tunnel barrier layer TB. The nonmagnet 32 is provided between the ferromagnet 31 and the ferromagnet 33, and forms, together with these ferromagnet 31 and ferromagnet 33, a magnetic tunnel junction. Furthermore, in a case where an initial amorphous layer such as cobalt-iron-boron (CoFeB) is used as an interface layer of the ferromagnet 31 and the ferromagnet 33, the nonmagnet 32 functions as a seed material that provides a nucleus for growth of a crystalline film from an interface between the ferromagnet 31 and the nonmagnet 32. Similarly, in a case where cobalt-iron-boron (CoFeB) is used as an interface layer of the ferromagnet 33, the nonmagnet 32 also functions as a seed material with respect to the ferromagnet 33. Herein, the initial amorphous layer is a layer which is in an amorphous state immediately after film formation and which crystalizes after annealing processing. The nonmagnet 32 has a tetragonal or cubic structure in which its film plane is oriented in a (001) plane. An example of an oxide used for the nonmagnet 32 is magnesium oxide (MgO). Magnesium oxide (MgO) has a NaCl structure. In a case where magnesium oxide (MgO) is used for the nonmagnet 32, the (001) interface of magnesium oxide (MgO) and the (001) interface of cobalt-iron-boron (CoFeB) are matched with each other. For this reason, the cobalt-iron-boron (CoFeB) is crystal-grown through annealing processing, thereby having a (001)-oriented, body-centered cubic structure.

The ferromagnet 33 is provided on the lower surface of the nonmagnet 32. The ferromagnet 33 is a conductive film having ferromagnetic properties. The ferromagnet 33 is used as a reference layer RL. The ferromagnet 33 has a direction of an easy axis of magnetization in a direction (Z direction) perpendicular to the film surface. A magnetization direction of the ferromagnet 33 is fixed. In the example shown in FIG. 6, the magnetization direction of the ferromagnet 33 corresponds to the direction extending from the ferromagnet 33 to the ferromagnet 31. The “magnetization direction” being “fixed” means that the magnetization direction is not changed by a torque of a magnitude that could invert the magnetization direction of the ferromagnet 31. Usually, an interface layer is used for the ferromagnet 33. As an interface layer of the ferromagnet 33, an initial amorphous layer, such as cobalt-iron-boron (CoFeB), etc., is used. Furthermore, a secondary ferromagnetic layer is provided so as to be in contact with a surface of the cobalt-iron-boron (CoFeB) layer opposite to a surface in contact with the magnesium oxide (MgO) layer. The secondary ferromagnetic layer includes at least one alloy film selected from, for example, cobalt platinum (CoPt), cobalt nickel (CoNi), and cobalt palladium (CoPd). The secondary ferromagnetic layer is a stacked film such as a stacked film including Co/Pt or a stacked film including Co/Pd. The cobalt-iron-boron (CoFeB) layer that serves as an initial amorphous layer is used by being stacked with a stacked film including the above-described CoPt, CoPd, and Co/Pt, a stacked film including Co/Pd, etc., described above. In this case, in the interface layer of the ferromagnet 33 such as, for example, the aforementioned CoFeB layer, (001)-oriented MgO is formed closer to the nonmagnet 32 than the other layers.

The nonmagnet 34 is provided on a lower surface of the ferromagnet 33. The nonmagnet 34 is a conductive film having nonmagnetic properties. The nonmagnet 34 is used as a spacer layer SP. The nonmagnet 34 includes an element selected from, for example, ruthenium (Ru), osmium (Os), rhodium (Rh), iridium (Ir), vanadium (V), and chrome (Cr), or an alloy thereof. The nonmagnet 34 has a thickness of, for example, 2 nanometers (nm) or smaller.

The ferromagnet 35 is provided on the lower surface of the nonmagnet 34. In other words, the ferromagnet 35 is provided on the side opposite to the ferromagnet 31 with respect to the ferromagnet 33. The ferromagnet 35 is a conductive film having ferromagnetic properties. The ferromagnet 35 is used as a shift canceling layer SCL. The ferromagnet 35 has a direction of an easy axis of magnetization in a direction (Z direction) perpendicular to the film surface. A magnetization direction of the ferromagnet 35 is fixed. In the example shown in FIG. 6, the magnetization direction of the ferromagnet 35 corresponds to the direction extending from the ferromagnet 33 to the ferromagnet 35. The ferromagnet 35 includes at least one alloy layer selected from, for example, cobalt platinum (CoPt), cobalt nickel (CoNi), and cobalt palladium (CoPd). The ferromagnet 35 may be a stacked film such as a stacked film including Co/Pt, a stacked film including Co/Pd, etc.

The ferromagnet 33 and the ferromagnet 35 are antiferromagnetically coupled by the nonmagnet 34. That is, the ferromagnet 33 and the ferromagnet 35 are coupled in such a manner that their magnetization directions are anti-parallel to each other. Such a coupling structure of the ferromagnet 33, the nonmagnet 34, and the ferromagnet 35 is referred to as a synthetic anti-ferromagnetic (SAF) structure. The SAF structure enables the ferromagnet 35 to cancel the influence of a leak field of the ferromagnet 33 on changing of the magnetization direction of the ferromagnet 31. This allows the ferromagnet 35 to reduce a substantial leak field of the ferromagnet 33.

The nonmagnet 36 is provided on a lower surface of the ferromagnet 35. The nonmagnet 36 is a conductive film having nonmagnetic properties. The nonmagnet 36 is used as an under layer UL. A nonmagnet 36 may include at least one element selected from, for example, zirconium (Zr), hafnium (Hf), tungsten (W), chrome (Cr), molybdenum (Mo), niobium (Nb), titanium (Ti), tantalum (Ta), vanadium (V), ruthenium (Ru), and platinum (Pt).

The MTJ body 26 may take either a low-resistance state or a high-resistance state, depending on whether the relative relationship between the magnetization directions of the storage layer SL and the reference layer RL is parallel or anti-parallel. In the present embodiment, the magnetization direction of the storage layer SL with respect to the magnetization direction of the reference layer RL is controlled by causing a write current to flow in the MTJ body 26. Specifically, a write method using a spin transfer torque generated by causing a current to flow in the MTJ body 26 is adopted.

In a case where a write current Ic0 of a given magnitude is caused to flow through the MTJ body 26 in a direction from the storage layer SL to the reference RL, that is, the direction indicated by arrow A1 in FIG. 6, the relative relationship between the magnetization directions of the storage layer SL and the reference layer RL becomes parallel. In this parallel state, the resistance of the MTJ body 26 takes the minimum value, and the MTJ body 26 is set to the low-resistance state. This low-resistance state is called a “P (parallel) state”, and is defined as, for example, a state of data “0”.

Furthermore, in a case where a write current Ic1 greater than the write current Ic0 is caused to flow through the MTJ body 26 in a direction from the reference layer RL to the storage layer SL, that is, the direction indicated by arrow A2 in FIG. 6, the relative relationship between the magnetization directions of the storage layer SL and the reference layer RL becomes anti-parallel. In this anti-parallel state, the resistance of the MTJ body 26 takes the maximum value, and the MTJ body 26 is set to a high-resistance state. This high-resistance state is called an “anti-parallel (AP) state”, and is defined as, for example, the state of data “1”.

How data “1” and data “0” are defined is not limited to the example described above. For example, the P state may be defined as data “1”, and the AP state may be defined as data “0”.

Furthermore, the MTJ body 26 is not limited to the structure shown in FIG. 6. The MTJ body 26 may include, for example, another layer or other layers, and each of the ferromagnets and nonmagnets may be composed of a plurality of layers.

### 1.2 Method of Manufacturing Memory Cell Array

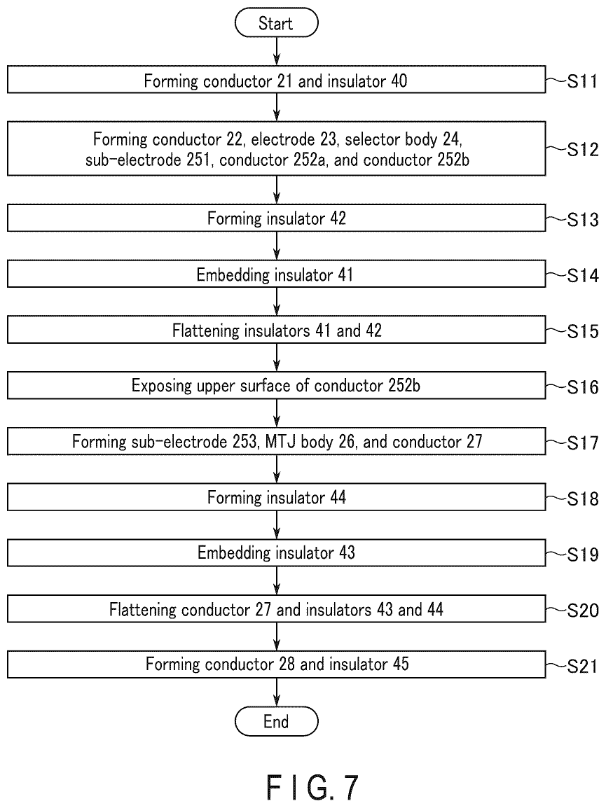

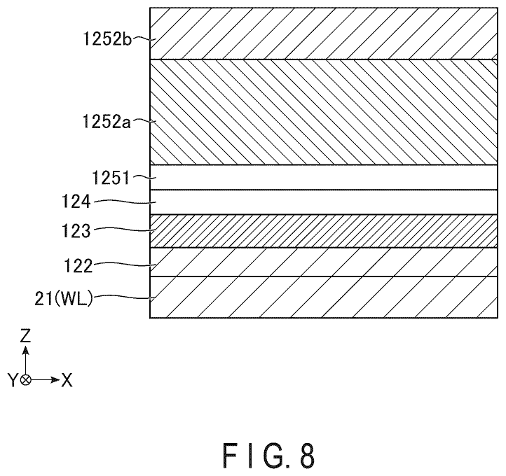

Next, a method of manufacturing the memory cell array 10 of the magnetic memory device 1 according to the first embodiment will be described. FIG. 7 is a flowchart showing an example of a method of manufacturing the memory cell array 10 in the magnetic memory device 1 according to the first embodiment. FIG. 8 to FIG. 15 are each a cross-sectional view for illustrating an example of the method of manufacturing the memory cell array 10 in the magnetic memory device 1 according to the first embodiment. FIG. 8 to FIG. 15 are each a cross-sectional view corresponding to FIG. 4.

First, in S11 of FIG. 7, the plurality of conductors 21 and the insulator 40 are formed on an upper surface of the semiconductor substrate (not shown) serving as a wafer WF.

Specifically, after a conductor layer is provided on the upper surface of the semiconductor substrate, a mask in which a portion excluding regions corresponding to the word lines WL is opened is formed through photolithography, etc. Through anisotropic etching using the formed mask, the conductor layer is separated into the plurality of conductors 21 aligned in the Y direction, and holes that reach the semiconductor substrate are formed. The anisotropic etching in this step is, for example, reactive ion etching (RIE). Thereafter, the insulator 40 is embedded in the formed holes. This results in formation of the insulator 40.

Next, in S12 of FIG. 7, the conductor 22, the electrode 23, the selector body 24, the sub-electrode 251, the conductor 252a, and the conductor 252b are formed on the upper surface of each of the plurality of conductors 21.

Specifically, as shown in FIG. 8, a conductor layer 122, an electrode layer 123, a selector layer 124, a sub-electrode layer 1251, a conductor layer 1252a, and a conductor layer 1252b are formed in this order on the upper surfaces of the plurality of conductors 21 and the upper surface of the insulator 40.

The sub-electrode layer 1251 includes at least one element or compound selected from, for example, carbon (C) and carbon nitride (CN). The sub-electrode layer 1251 includes, for example, carbon (C). The conductor layers 1252a and 1252b include at least one element or compound selected from a high-melting-point metal and a compound of a high-melting-point metal element. The conductor layers 1252a and 1252b include, for example, titanium nitride (TiN). Furthermore, the conductor layer 1252b includes at least one element or compound selected from aluminum (Al), silicon (Si), boron (B), and carbon (C). The conductor layer 1252b includes, for example, aluminum (Al).

The conductor layers 1252a and 1252b are formed through, for example, sputtering, as will be described below. In sputtering in this series of steps, a step of forming the conductor layer 1252a and a step of forming the conductor layer 1252b are performed continuously. First, the conductor layer 1252a is formed on an upper surface of the sub-electrode layer 1251 (above the selector layer 124) through sputtering using a conductive material (at least one element or compound selected from a high-melting-point metal and a compound of a high-melting-point metal element). The conductor layer 1252a has a thickness of, for example, 20 nanometers (nm). Subsequently, the conductor layer 1252b is formed on an upper surface of the conductor layer 1252a through sputtering using a conductive material (at least one element or compound selected from a high-melting-point metal and a compound of a high-melting-point metal element) and an impurity (at least one element or compound selected from aluminum (Al), silicon (Si), boron (B), and carbon (C)). In the step of forming the conductor layer 1252b, the aforementioned impurity is added to secure the flatness. This provides the conductor 252b with an amorphous structure. The thickness of the conductor layer 1252b is greater than the amount (thickness) removed by over-etching to be described later. The thickness of the conductor layer 1252b corresponds to, for example, the amount (thickness) removed by over-etching +10 nanometers (nm). The amount removed by over-etching is, for example, 3 nanometers (nm) or greater and 5 nanometers (nm) or smaller. Meanwhile, the conductor layers 1252a and 1252b may be formed through atomic layer deposition (ALD) or chemical vapor deposition (CVD) in a similar manner to the manner described above.

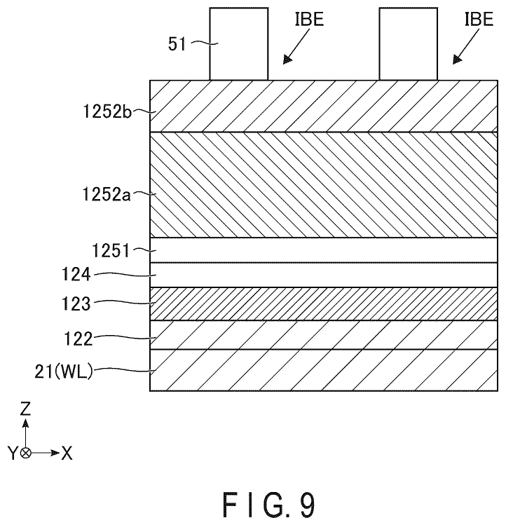

Next, as shown in FIG. 9, a plurality of masks 51 are formed. The plurality of masks 51 correspond to a set of the conductor layer 122, the electrode layer 123, the selector layer 124, the sub-electrode layer 1251, the conductor layer 1252a, and the conductor layer 1252b, in which a portion excluding regions corresponding to the conductor 22, the electrode 23, the selector body 24, the sub-electrode 251, and the sub-electrode 252, which are to be manufactured, is opened through photolithography, etc. The plurality of masks 51 include, for example, titanium nitride (TiN), and protect portions which are to function as the conductor 22, the electrode 23, the selector body 24, the sub-electrode 251, and the sub-electrode 252 in ion beam etching (IBE) to be described later. The plurality of masks 51 are formed into columnar structures aligned in a matrix on an upper surface of the conductor layer 1252b, for example, and each of the columnar structures protects a region corresponding to one memory cell MC.

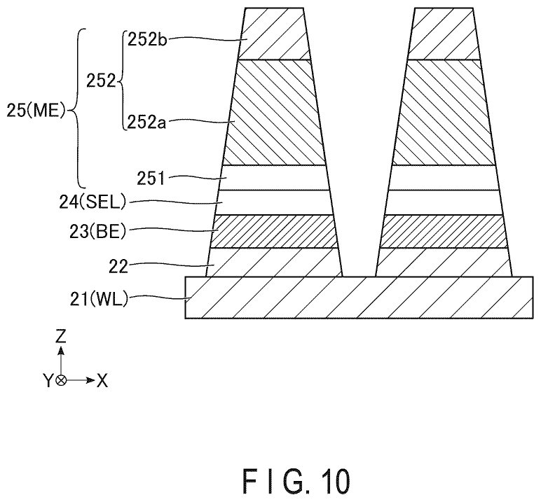

Next, as shown in FIG. 9, the conductor layer 122, the electrode layer 123, the selector layer 124, the sub-electrode layer 1251, the conductor layer 1252a, and the conductor layer 1252b are etched through ion beam etching. This removes portions of the set of the conductor layer 122, the electrode layer 123, the selector layer 124, the sub-electrode layer 1251, the conductor layer 1252a, and the conductor layer 1252b, the portions being not protected by the plurality of masks 51, so that the plurality of conductors 21 and the insulator 40 positioned below the aforementioned portions are exposed. Such ion beam etching as described above, as shown in FIG. 10, processes the conductor layer 122, the electrode layer 123, the selector layer 124, the sub-electrode layer 1251, the conductor layer 1252a, and the conductor layer 1252b, thereby forming the plurality of conductors 22, the plurality of electrodes 23, the plurality of selector bodies 24, the plurality of sub-electrodes 251, the plurality of conductors 252a, and the plurality of conductors 252b. That is, a structure in which each conductor 22, each electrode 23, each selector body 24, each sub-electrode 251, each conductor 252a, and each conductor 252b are stacked is formed. In other words, the plurality of first layer stacks each including the conductor 22, the electrode 23, the selector body 24, the sub-electrode 251, and the sub-electrode 252 are formed.

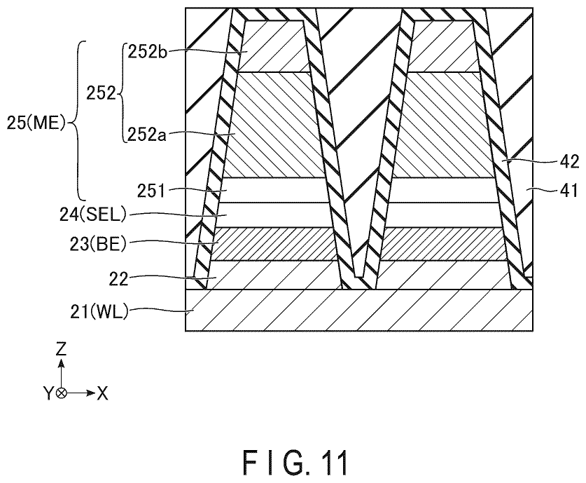

Next, in S13 of FIG. 7, the insulator 42 is formed on the upper surface of each of the plurality of conductors 21, the upper surface of the insulator 40, an upper surface of each of the plurality of first layer stacks, and a side surface of each of the plurality of first layer stacks, as shown in FIG. 11. That is, the insulator 42 is formed on the upper surface of the conductor 252b and a side surface of each of the conductor 22, the electrode 23, the selector body 24, the sub-electrode 251, the conductor 252a, and the conductor 252b.

Next, in S14 of FIG. 7, as shown in FIG. 11, the insulator 41 is embedded in a range from a position of the upper surface of the insulator 42 provided on the upper surface of the conductor 21 to a position of the upper surface of the insulator 42 provided on the upper surface of the conductor 252b.

Next, in S15 of FIG. 7, as shown in FIG. 11, the upper surface of the insulator 41 and the upper surface of the insulator 42 are flattened. The flattening in this step is performed through, for example, chemical mechanical polishing (CMP).

Next, in S16 of FIG. 7, the upper surface of the conductor 252b is exposed.

Specifically, a portion of the insulator 41, a portion of the insulator 42, and a portion of the upper surface of the conductor 252b are removed to expose the upper surface of the conductor 252b through etch-back.

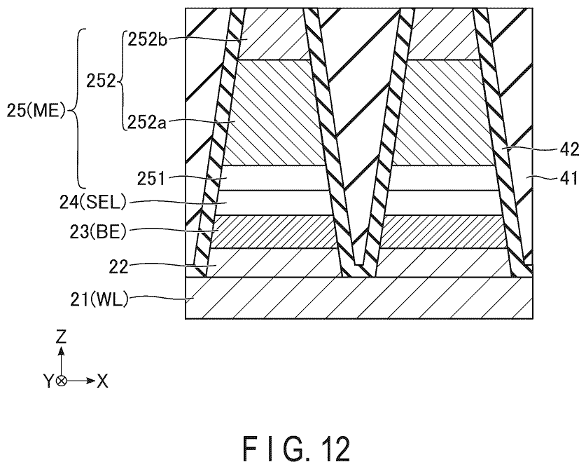

After the flattening in S15 of FIG. 7 is performed, the thickness of the insulator 42 may be different between the vicinity of a center and the vicinity of an end portion of a region MAT in which the memory cell array 10 is to be arranged. For example, the thickness of the insulator 42 in the vicinity of the center may be greater than the thickness of the insulator 42 in the vicinity of the end portion. Therefore, this step performs over-etching by the amount of difference between the thickness of the insulator 42 in the vicinity of the center and the thickness of the insulator 42 in the vicinity of the end portion in order to expose the upper surfaces of all of the conductors 252b arranged in the region MAT. For example, a time for etch-back is set to be lower by about 30% by setting etching rates such that a ratio of an etching rate of the aforementioned conductive material (e.g., titanium nitride) included in the conductors 252a and 252b to an etching rate of an insulating material (e.g., silicon nitride) included in the insulators 42 and 43 becomes about 1. This removes not only a part of the insulator 41 and a part of the insulator 42 but also a part of the upper surface of the conductor 252b, thereby exposing the upper surface of the conductor 252b, as shown in FIG. 12. The conductor 252b after etch-back has a thickness of, for example, 10 nanometers (nm). The etch-back in this step is, for example, RIE.

Next, in S17 of FIG. 7, the sub-electrode 253, the MTJ body 26, and the conductor 27 are formed on the upper surface of each of the plurality of first layer stacks.

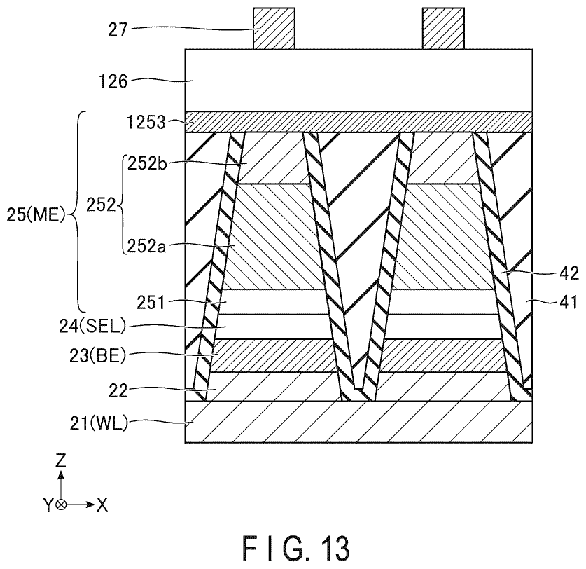

Specifically, as shown in FIG. 13, a sub-electrode layer 1253 and an MTJ layer 126 are formed in this order on the upper surface of the conductor 252b, the upper surface of the insulator 41, and the upper surface of the insulator 42. The MTJ layer 126 is a layer stack in which the respective layers included in the MTJ body 26 described with reference to FIG. 6 are formed in a planar fashion in this stacking order.

Next, the plurality of conductors 27 are formed. The plurality of conductors 27 correspond to a set of the sub-electrode layer 1253 and the MTJ layer 126 in which a portion excluding regions corresponding to the sub-electrode 253 and the MTJ body 26, which are to be manufactured, is opened through photolithography, etc. The plurality of conductors 27 include, for example, titanium nitride, and protect portions which are to function as the sub-electrode 253 and the MTJ body 26 in ion beam etching. The plurality of conductors 27 are formed into columnar structures aligned in a matrix on an upper surface of the MTJ layer 126, for example, and each of the columnar structures protects a region corresponding to one memory cell MC.

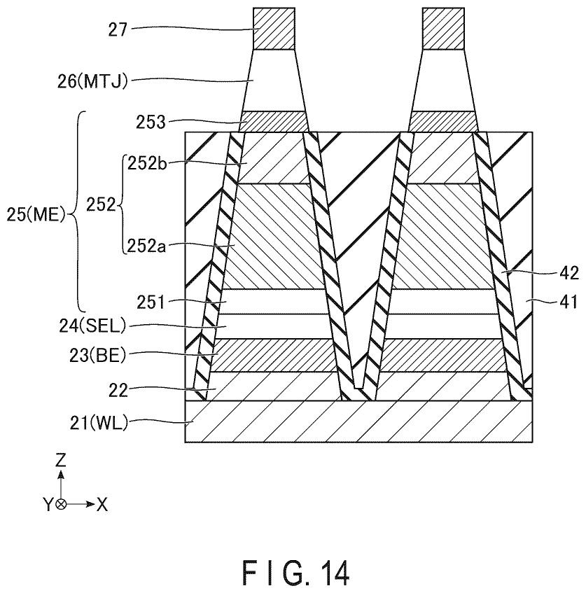

Next, the sub-electrode layer 1253 and the MTJ layer 126 are etched through ion beam etching. This removes a portion of the set of the sub-electrode layer 1253 and the MTJ layer 126, the portion being not protected by the plurality of conductors 27, so that the insulators 41 and 42 positioned below the aforementioned portions are exposed. Such ion beam etching as described above, as shown in FIG. 14, processes the sub-electrode layer 1253 and the MTJ layer 126, thereby forming the plurality of sub-electrodes 253 and the plurality of MTJ bodies 26. The sub-electrode 253 is formed on the upper surface of the conductor 252b. The MTJ body 26 is formed on the upper surface of the sub-electrode 253 (above the conductor 252b). That is, a structure in which the sub-electrode 253, the MTJ body 26, and the conductor 27 are stacked is formed. In other words, the plurality of second layer stacks each including the sub-electrode 253, the MTJ body 26, and the conductor 27 are formed.

Next, in S18 of FIG. 7, the insulator 44 is formed on the upper surface of the insulator 41, the upper surface of the insulator 42, and a side surface of each of the plurality of second layer stacks.

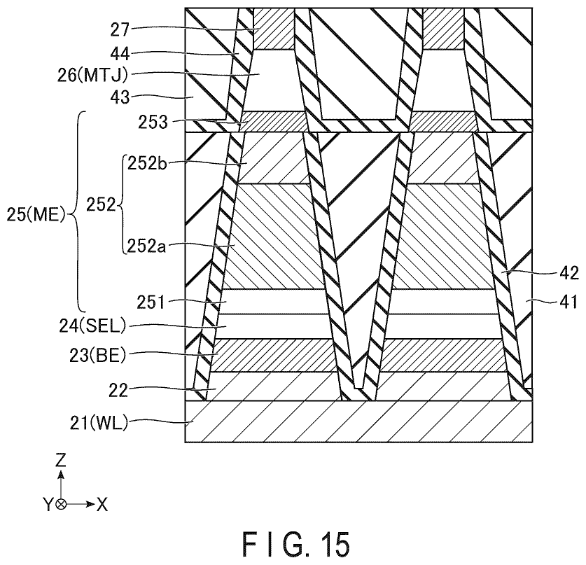

Specifically, after formation of the insulating layer on the upper surface of the insulator 41, the upper surface of the insulator 42, an upper surface of each of the plurality of second layer stacks, and the side surface of each of the plurality of second layer stacks, the insulator on the upper surface of each of the plurality of second layer stacks is removed through etch-back. This results in formation of the insulator 44, as shown in FIG. 15.

Next, in S19 of FIG. 7, as shown in FIG. 15, the insulator 43 is embedded in a range from a position of the upper surface of the insulator 44 provided on the upper surface of the insulator 41 to a position of the upper surface of the conductor 27.

Next, in S20 of FIG. 7, as shown in FIG. 15, the upper surface of the conductor 27, an upper surface of the insulator 43, and the upper surface of the insulator 44 are flattened. The flattening in this step is performed through, for example, CMP.

Next, in S21 of FIG. 7, the plurality of conductors 28 and the insulator 45 are formed on the upper surfaces of the plurality of second layer stacks, the upper surface of the insulator 43, and the upper surface of the insulator 44.

Specifically, after a conductor layer is provided on the upper surfaces of the plurality of second layer stacks, the upper surface of the insulator 43, and the upper surface of the insulator 44, a mask in which a portion excluding regions corresponding to the bit lines BL is opened through photolithography, etc., is formed. Through anisotropic etching using the formed mask, the conductor layer is separated into the plurality of conductors 28 aligned in the X direction, and holes that reach the insulators 43 and 44 are formed. The anisotropic etching in the present step is, for example, the RIE. Thereafter, the insulator 45 is embedded in the formed holes. This results in formation of the insulator 45.

As described above, a stacked structure shown in FIG. 4 and FIG. 5 is formed by performing S11 to S21 of FIG. 7.

In the manner described above, a structure corresponding to the memory cell array 10 is formed on the wafer WF. The wafer WF is diced into chips, so that the magnetic memory device 1 is formed.

The magnetic memory device 1 is formed through the manufacturing steps described above. The manufacturing steps described above are merely an example and are not limited thereto. For example, another step may be inserted between the manufacturing steps, and some of the steps may be omitted or integrated. Furthermore, the respective manufacturing steps may be interchanged where possible.

### 1.3 Advantageous Effect of Present Embodiment

The magnetic memory device 1 according to the first embodiment described above can secure the flatness of the electrode 25 (middle electrode ME). Hereinafter, effects of the magnetic memory device 1 according to the first embodiment will be described in detail.

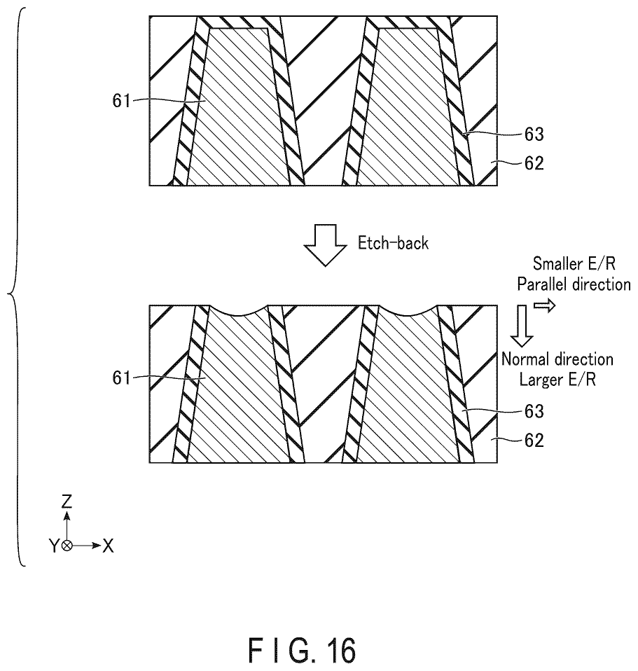

FIG. 16 is a cross-sectional view for illustrating a step of exposing an upper surface of a middle electrode in a method of manufacturing a memory cell array in a magnetic memory device according to a comparative example. A magnetic memory device according to the comparative example includes a selector body, an MTJ body provided above the selector body, and each middle electrode 61 provided between the selector body and the MTJ body. FIG. 16 extracts and shows the middle electrodes 61, insulators 63 each provided on an upper surface and a side surface of each middle electrode 61, and insulators 62 each embedded between the insulators 63 included in the magnetic memory device according to the comparative example. The middle electrode 61 includes, for example, titanium nitride. The middle electrode 61 has a crystal structure. The insulators 62 and 63 include, for example, silicon nitride.

In a case of performing over-etching (etch-back) by setting a ratio of an etching rate of titanium nitride included in the middle electrode 61 to an etching rate of silicon nitride included in the insulators 62 and 63 to about 1, it is ideal that the upper surface of the middle electrode 61 be flush with the upper surfaces of the insulators 62 and 63 after etching.

However, in reality, titanium nitride may be etched more than silicon nitride (titanium nitride may be excessively etched), so that the upper surface of the middle electrode 61 may be etched below the upper surfaces of the insulators 62 and 63, and as a result, as shown in FIG. 16, the upper surface of the middle electrode 61 may be formed into a downwardly convex shape. Furthermore, the height (depth) of the convex shape increases as the etching progresses.

It is known that in a crystal structure of titanium nitride, a (111) plane has a preferred orientation on silicon oxide (SiO₂), that is, the preferred orientation is in the direction perpendicular to the film surface (upper surface) (hereinafter referred to as a “normal direction”). Because titanium nitride has such an orientation, and because the height of the convex shape increases as etching progresses as described above, it is considered that the reason titanium nitride is etched excessively is that the etching rate differs depending on the plane orientation of the crystal plane. More specifically, as shown in FIG. 16, it is considered that the etching rate (E/R) in the normal direction is greater than the etching rate (E/R) in the direction parallel to the film surface (upper surface) (hereinafter referred to as a “parallel direction”). In other words, it is considered that the crystalline nature of titanium nitride may cause the titanium nitride to be etched excessively.

The present embodiment forms the selector layer 124, forms the conductor layer 1252a above the selector layer 124 using the aforementioned conductive material, and forms the conductor layer 1252b on the upper surface of the conductor layer 1252a using the aforementioned conductive material and the aforementioned impurity. The conductor layer 1252b to which the aforementioned impurity is added has an amorphous structure. The selector layer 124 and the conductor layers 1252a and 1252b thus formed are processed to form the selector body 24 and the sub-electrode 252 including the conductors 252a and 252b. The conductor layers 1252a and 1252b (sub-electrode 252) have a preferred orientation in the normal direction; however, the conductor 252b having an amorphous structure formed as described above has no difference in etching rate between the normal direction and the parallel direction. Therefore, in the step of exposing the conductor 252b (S16 of FIG. 7), the upper surface of conductor 252b does not take the downwardly convex shape, and the upper surface of the conductor 252b is greater in flatness than that of the middle electrode 61 having a crystal structure shown in FIG. 16 (a case of a crystal structure in which the upper surface is formed into a downwardly convex through an etch-back process). Therefore, the upper surface of the sub-electrode 253 provided on the upper surface of the conductor 252b is also greater in flatness than that of the sub-electrode 253 provided on the upper surface of a crystal structure in which the upper surface is formed into a downwardly convex shape through an etch-back process. Therefore, the magnetic memory device 1 and the method of manufacturing the magnetic memory device 1 according to the present embodiment can secure the flatness of the electrode 25. In addition, the upper surface of the sub-electrode 253 is greater in flatness than that of the sub-electrode 253 provided on the upper surface of a crystal structure in which the upper surface is formed into a downwardly convex shape through an etch-back process. As a result, the upper surfaces of the respective layers included in the MTJ body 26 provided on the upper surface of the sub-electrode 253 are also greater in flatness than those in the MTJ body 26 provided on the upper surface of a sub-electrode 253 provided on the upper surface of a crystal structure in which the upper surface is formed into a downwardly convex shape through an etch-back process. Therefore, the magnetic memory device 1 and the method of manufacturing the magnetic memory device 1 according to the present embodiment can improve the characteristics (e.g., a coercive force) of the MTJ body 26.

Furthermore, the thickness of the conductor 252b is smaller than that of the conductor 252a. Therefore, the sub-electrode 252 has a smaller resistance than the sub-electrode 252, the entirety of which has an amorphous structure. Accordingly, the magnetic memory device 1 and the method of manufacturing the magnetic memory device 1 according to the present embodiment can reduce the resistance of the electrode 25 as compared to a case in which the entirety of the sub-electrode 252 has an amorphous structure.

### 2. Second Embodiment

A magnetic memory device according to a second embodiment will be described. A magnetic memory device 1A according to the second embodiment differs from that of the first embodiment in terms of the cross-sectional structure of the sub-electrode 252 and the method of manufacturing a memory cell array 10A. The following description will concentrate on the features different form the first embodiment.

### 2.1 Cross-Sectional Structure of Memory Cell Array

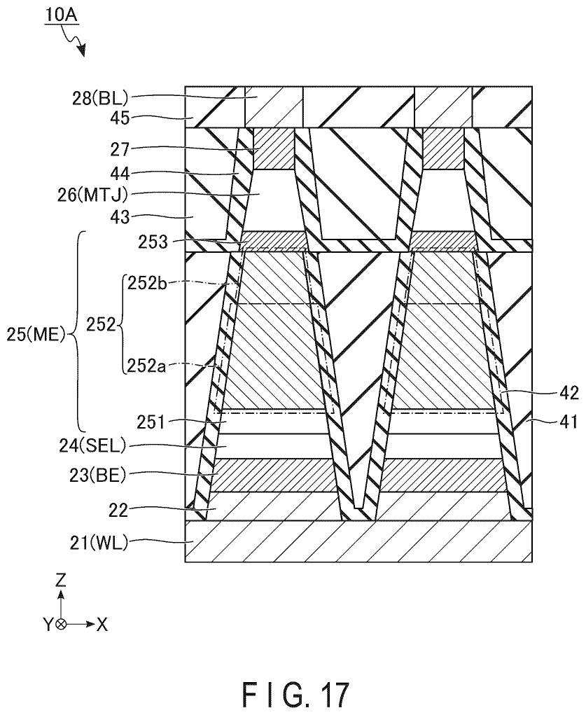

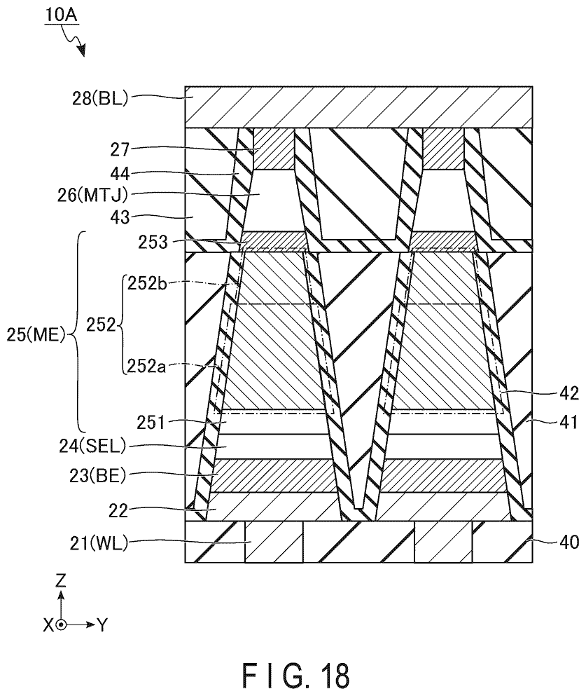

An example of the cross-sectional structure of the memory cell array 10A will be described with reference to FIG. 17 and FIG. 18. FIG. 17 is a cross-sectional view taken along line IV-IV of FIG. 3 described in the first embodiment, and shows an example of a cross-sectional structure of the memory cell array 10A included in the magnetic memory device 1A according to the second embodiment. FIG. 18 is a cross-sectional view taken along line V-V of FIG. 3 described in the first embodiment, and shows an example of the cross-sectional structure of the memory cell array 10A included in the magnetic memory device 1A according to the second embodiment.

As shown in FIG. 17 and FIG. 18, the memory cell array 10A includes the plurality of conductors 21, the plurality of conductors 22, the plurality of electrodes 23, the plurality of selector bodies 24, the plurality of electrodes 25, the plurality of MTJ bodies 26, the plurality of conductors 27, the plurality of conductors 28, and the insulators 40 to 45.

The sub-electrode 252 is formed of a conductive material and includes at least one element or compound selected from, for example, a high-melting-point metal element and a compound thereof. Such a conductive material includes at least one element or compound selected from, for example, titanium (Ti), tantalum (Ta), tungsten (W), titanium nitride (TiN), tantalum nitride (TaN), and tungsten nitride (WN). Furthermore, the sub-electrode 252 includes an impurity. For the electrode 25 to function as an electrode, a material that allows the sub-electrode 252 to have conductivity while including an impurity is used as the impurity included in the sub-electrode 252. Such an impurity includes at least one element or compound selected from, for example, aluminum (Al), silicon (Si), boron (B), and carbon (C). As described above, the sub-electrode 252 includes a compound of the aforementioned conductive material and the aforementioned impurity, and has conductivity. The aforementioned conductive material and the aforementioned impurity used for the sub-electrode 252 are combined as appropriate. The sub-electrode 252 has a thickness of, for example, 20 nanometers (nm) or greater and 50 nanometers (nm) or smaller.

Meanwhile, the sub-electrode 252 may include impurities such as an element included in gas used in manufacturing steps of the magnetic memory device 1A, or an element mixed into the portion described above from the periphery of the portion. The sub-electrode 252 may include impurities different from the impurity described above.

The sub-electrode 252 includes conductors 252a and 252b. The conductor 252b is positioned on the upper side of the sub-electrode 252. In other words, the conductor 252b is positioned closer to the MTJ body 26 than the conductor 252a and is in contact with the conductor 252a. Since the conductor 252b is formed by ion implantation, which will be described later, the sub-electrode 252 has a gradient of a concentration of the aforementioned impurity in a direction (normal direction) perpendicular to the upper surface of the sub-electrode 252, and the conductors 252a and 252b are integrated. The conductor 252b is higher in the concentration of the impurity described above than the conductor 252a. The conductor 252b is a portion of the sub-electrode 252 in which the concentration of the aforementioned impurity is relatively high. The conductor 252b has an amorphous structure. As will be described later, the upper surface of the conductor 252b is greater in flatness than that in the crystal structure in which the upper surface is formed into a downwardly convex shape through the etch-back process. The thickness of the conductor 252b corresponds to, for example, the depth to which ions are implanted through ion implantation. The peak in the concentration of the aforementioned impurity exists within the range from the upper surface of the conductor 252b to the depth of the ions implanted through ion implantation. In other words, the sub-electrode 252 has a peak in the concentration of the aforementioned impurity within the conductor 252b. The conductor 252a is a portion of the sub-electrode 252 in which the concentration of the aforementioned impurity is relatively low. In the conductor 252a, the concentration of the aforementioned impurity decreases toward the lower surface of the sub-electrode 252. The conductor 252a has a crystal structure.

The cross-sectional structure of the memory cell array 10A other than the sub-electrode 252 is similar to that shown in FIG. 4 and FIG. 5 described in the first embodiment.

### 2.2 Method of Manufacturing Memory Cell Array

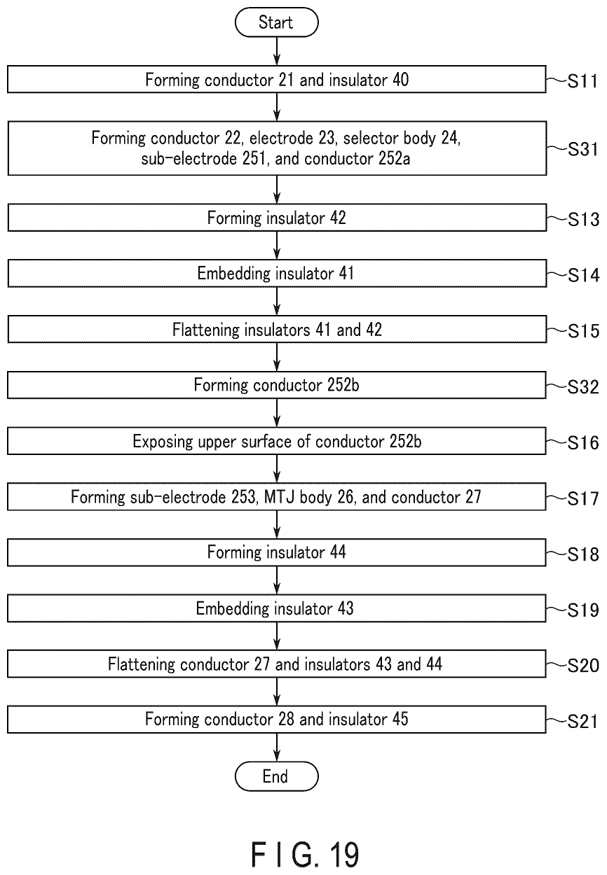

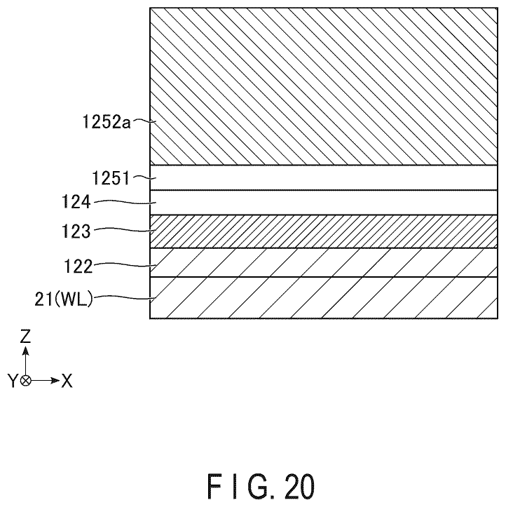

The method of manufacturing the memory cell array 10A of the magnetic memory device 1A according to the second embodiment will be described. FIG. 19 is a flowchart showing an example of a method of manufacturing the memory cell array 10A in the magnetic memory device 1A according to the second embodiment. FIG. 20 to FIG. 26 are each a cross-sectional view for illustrating an example of the method of manufacturing the memory cell array 10A in the magnetic memory device 1A according to the second embodiment. FIG. 20 to FIG. 26 are each a cross-sectional view corresponding to FIG. 17.

The flowchart shown in FIG. 19 replaces S12 of the flowchart in FIG. 7 described in the first embodiment with S31 and additionally includes S32 between S15 and S16 of the flowchart in FIG. 7. Except for S31 and S32, the flowchart shown in FIG. 19 is the same as the flowchart of FIG. 7 described in the first embodiment.

First, after execution of S11 of FIG. 19 in a similar manner to the first embodiment, in S31 of FIG. 19, the conductor 22, the electrode 23, the selector body 24, the sub-electrode 251, and the conductor 252a are formed on the upper surface of each of the plurality of conductors 21.

Specifically, as shown in FIG. 20, the conductor layer 122, the electrode layer 123, the selector layer 124, the sub-electrode layer 1251, and the conductor layer 1252a are formed in this order on the upper surfaces of the plurality of conductors 21 and the insulator 40.

The sub-electrode layer 1251 includes at least one element or compound selected from carbon (C) and carbon nitride (CN). The sub-electrode layer 1251 includes, for example, carbon (C). The conductor layer 1252a includes at least one element or compound selected from a high-melting-point metal and a compound of a high-melting-point metal element. The conductor layer 1252a includes, for example, titanium nitride (TiN).

The conductor layer 1252a is formed through, for example, sputtering, as will be described below. The conductor layer 1252a is formed on the upper surface of the sub-electrode layer 1251 (above the selector layer 124) through sputtering using a conductive material (at least one element or compound selected from a high-melting-point metal and a compound of a high-melting-point metal element). The thickness of the conductor layer 1252a corresponds to, for example, the amount (thickness) removed by over-etching to be described later +30 nanometers (nm). The amount removed through over-etching is, for example, 3 nanometers (nm) or greater and 5 nanometers (nm) or smaller. Meanwhile, the conductor layer 1252a may be formed through ALD, CVD, etc., in a similar manner to the manner described above.

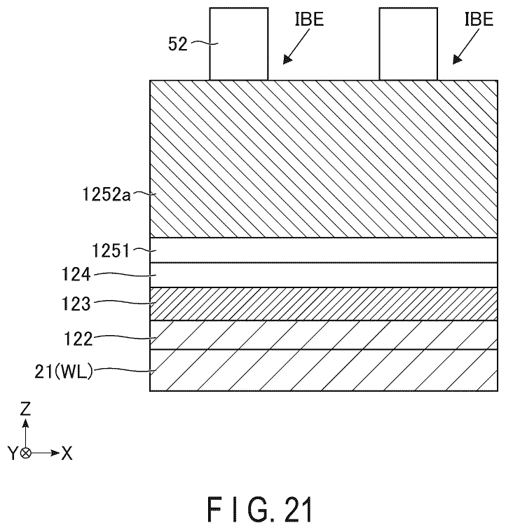

Next, as shown in FIG. 21, the plurality of masks 52 are formed. The plurality of masks 52 correspond to a set of the conductor layer 122, the electrode layer 123, the selector layer 124, the sub-electrode layer 1251, and the conductor layer 1252a, in which a portion excluding regions corresponding to the conductor 22, the electrode 23, the selector body 24, the sub-electrode 251, and the sub-electrode 252, which are to be manufactured, is opened through photolithography, etc. The plurality of masks 52 include, for example, titanium nitride (TiN), and protect portions which are to function as the conductor 22, the electrode 23, the selector body 24, the sub-electrode 251, and the sub-electrode 252 in ion beam etching. The plurality of masks 52 are formed into columnar structures aligned in a matrix on the upper surface of the conductor layer 1252a, for example, and each of the columnar structures protects a region corresponding to one memory cell MC.

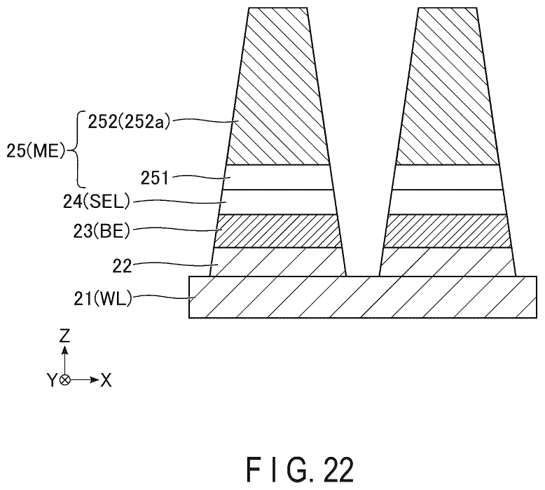

Next, as shown in FIG. 21, the conductor layer 122, the electrode layer 123, the selector layer 124, the sub-electrode layer 1251, and the conductor layer 1252a are etched through ion beam etching. This removes portions of the set of the conductor layer 122, the electrode layer 123, the selector layer 124, the sub-electrode layer 1251, and the conductor layer 1252a, the portions being not protected by the plurality of masks 52, so that the plurality of conductors 21 and the insulator 40 positioned below the aforementioned portions are exposed. Such ion beam etching as described above, as shown in FIG. 22, processes the conductor layer 122, the electrode layer 123, the selector layer 124, the sub-electrode layer 1251, and the conductor layer 1252a, thereby forming the plurality of conductors 22, the plurality of electrodes 23, the plurality of selector bodies 24, the plurality of sub-electrodes 251, and the plurality of conductors 252a. That is, a structure in which each conductor 22, each electrode 23, each selector body 24, each sub-electrode 251, and each conductor 252a are stacked is formed. In other words, the plurality of first layer stacks each including the conductor 22, the electrode 23, the selector body 24, the sub-electrode 251, and the sub-electrode 252 are formed.

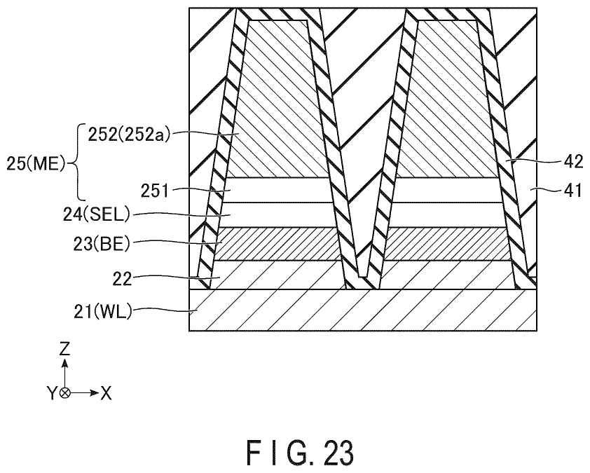

After execution of S31 of FIG. 19, S13 to S15 of FIG. 19 are executed in a similar manner to the first embodiment. First, as shown in FIG. 23, the insulator 42 is formed on the upper surface of each of the plurality of conductors 21, the upper surface of the insulator 40, the upper surface of each of the plurality of first layer stacks, and the side surface of each of the plurality of first layer stacks. That is, the insulator 42 is formed on the upper surface of the conductor 252a and the side surface of each of the conductor 22, the electrode 23, the selector body 24, the sub-electrode 251, and the conductor 252a. Next, the insulator 41 is embedded in a range from a position of the upper surface of the insulator 42 provided on the upper surface of the conductor 21 to a position of the upper surface of the insulator 42 provided on the upper surface of the conductor 252b. Next, an upper surface of the insulator 41 and the upper surface of the insulator 42 are flattened.

Next, in S32 of FIG. 19, the conductor 252b is formed into an upper portion of the conductor 252a.

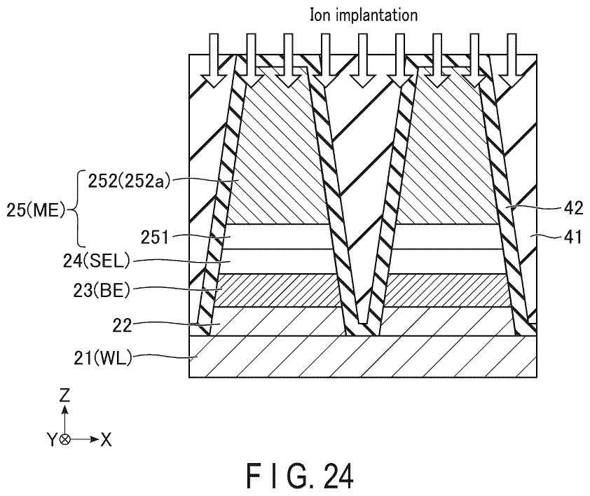

Specifically, as shown in FIG. 24, an impurity is added to the conductor 252a from the upper surface side of the conductor 252a through ion implantation. The impurity includes at least one element or compound selected from aluminum (Al), silicon (Si), boron (B), and carbon (C). The impurity includes, for example, aluminum (Al).

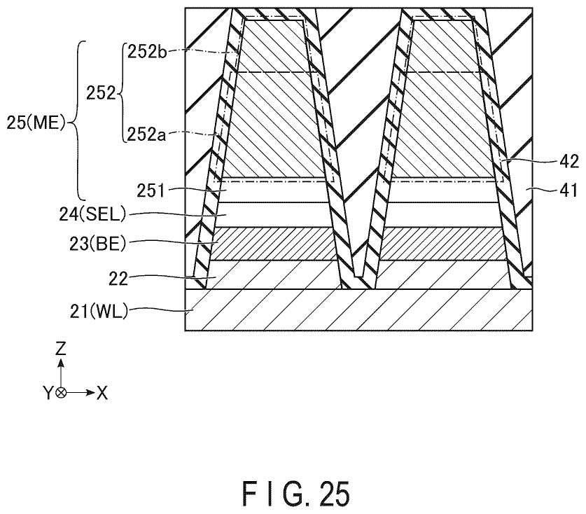

In a case where ions implanted through ion implantation reach the selector body 24 and the sub-electrode 251 (or the vicinities of the selector body 24 and the sub-electrode 251), the characteristics of the selector body 24 and the sub-electrode 251 may be degraded. Therefore, it is preferable that an acceleration voltage for use in ion implantation be set such that the ions do not reach the sub-electrode 251. Furthermore, it is preferable that, for example, the ion implantation depth be set to a depth smaller than half the film thickness of the sub-electrode 252 (for example, 10 nanometers (nm)), and a peak in the concentration of the impurity be set to a depth about half the ion implantation depth (for example, 5 nanometers (nm)). As a result, as shown in FIG. 25, the upper portion of the sub-electrode 252 changes from a crystalline structure to an amorphous structure, and the conductor 252b is formed in the upper portion of the sub-electrode 252.

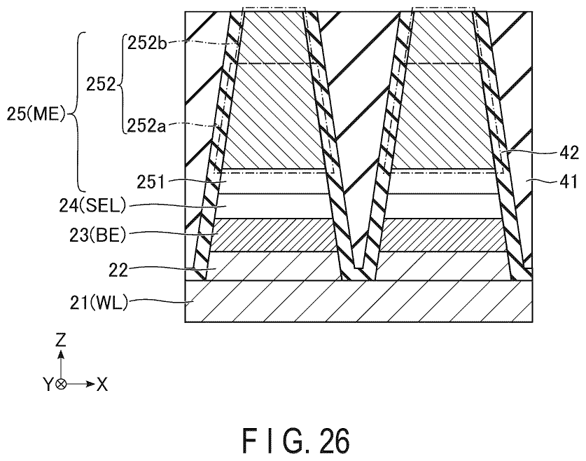

Next, S16 of FIG. 19 is performed in a similar manner to the first embodiment. This removes a part of the insulator 41, a part of the insulator 42, and a part of the upper surface of the conductor 252b, and exposes the upper surface of the conductor 252b, as shown in FIG. 26.

Thereafter, S17 to S21 of FIG. 19 are performed in a similar manner to the first embodiment. This results in formation of a stacked structure shown in FIG. 17 and FIG. 18.

In the manner described above, a structure corresponding to the memory cell array 10A is formed on the wafer WF. The wafer WF is then diced into chips to form the magnetic memory devices 1A.

The magnetic memory device 1A is formed through the manufacturing steps described above. The manufacturing steps described above are merely an example and are not limited thereto. For example, another step may be inserted between the manufacturing steps, and some of the steps may be omitted or integrated. Furthermore, the respective manufacturing steps may be interchanged where possible.

### 2.3 Advantageous Effect of Present Embodiment

The present embodiment forms the selector layer 124, and forms the conductor layer 1252a above the selector layer 124 using the aforementioned conductive material. The selector layer 124 and the conductor layer 1252a thus formed are processed to form the selector body 24 and the sub-electrode 252 including the conductor 252a. The aforementioned impurity is added to the conductor 252a from the upper surface of the conductor 252a. This results in formation of the conductor 252b in the upper portion of the conductor 252a (sub-electrode 252). The conductor 252b has an amorphous structure. Accordingly, the conductor 252b having the amorphous structure has no difference in etching rate between the normal direction and the parallel direction. Therefore, in the step of exposing the conductor 252b (S16 of FIG. 19), the upper surface of the conductor 252b does not take the downwardly convex shape, and the upper surface of the conductor 252b is greater in flatness than that in the crystal structure in which the upper surface is formed into a downwardly convex through an etch-back process. Therefore, the magnetic memory device 1A and the method of manufacturing the magnetic memory device 1A according to the present embodiment can secure the flatness of the electrode 25 and improve the characteristics of the MTJ body 26 as with the first embodiment.

Furthermore, by the aforementioned impurity being added through ion implantation, the conductor 252b is formed in the upper portion of the sub-electrode 252. Therefore, the sub-electrode 252 has a gradient of a concentration of the aforementioned impurity in the normal direction, and the conductors 252a and 252b are integrated. The conductor 252b is higher in the concentration of the impurity described above than the conductor 252a. The sub-electrode 252 has a peak in the concentration of the aforementioned impurity within the conductor 252b. Furthermore, an entry depth of ion implantation of the impurity is set to be smaller than half the film thickness of the sub-electrode 252 (a total of the film thicknesses of the respective conductors 252a and 252b integrated together). For example, in a case where the film thickness of the sub-electrode 252 is set to 30 nanometers (nm) and the entry depth of ion implantation of the impurity is set to 10 nanometers (nm), the thickness of the conductor 252a is equal to 20 nanometers (nm) and the thickness of the conductor 252b is equal to 10 nanometers (nm). Thereby, the thickness of the conductor 252b is smaller than that of the conductor 252a. Therefore, the sub-electrode 252 has a smaller resistance as compared to the sub-electrode 252, the entirety of which has an amorphous structure. Accordingly, the magnetic memory device 1A and the method of manufacturing the magnetic memory device 1A according to the present embodiment can reduce the resistance of the electrode 25 as compared to the case in which the entirety of the sub-electrode 252 has an amorphous structure, as with the first embodiment.

### 3. Modifications, etc.

As described above, a magnetic memory device (1) according to an embodiment includes a selector body (24), an MTJ body (26) provided above the selector body, and an electrode (25) provided between the selector body and the MTJ body. The electrode (25) includes a first sub-electrode (252) having a first conductor (252a) and a second conductor (252b) which is positioned closer to the MTJ body (26) than the first conductor and is in contact with the first conductor. The first conductor (252a) has a crystal structure. The second conductor (252b) has an amorphous structure.

The embodiments are not limited to those described in the above, and various modifications can be made.

Furthermore, the order of the steps in the flowchart described in the above embodiments may be altered to the extent possible.

In the first embodiment, the conductor 252b does not need to include a compound of the aforementioned conductive material and the aforementioned impurity. For example, the conductor 252b may be formed of a material (amorphous material) having an amorphous structure and may have conductivity. Such an amorphous material may be a material (an amorphous material not including a material of the conductor 252a) unrelated to the aforementioned conductive material. In such a case also, the upper surface of the conductor 252b is greater in flatness than that in the crystal structure in which the upper surface is formed into a downwardly convex shape through an etch-back process, as with the first embodiment. Furthermore, in such a case, for example, in the step of forming the conductor layer 1252a, the conductor layer 1252a is formed through sputtering using a conductive material (at least one element or compound selected from a high-melting-point metal and a compound of a high-melting-point metal element). In the step of forming the conductor layer 1252b, the conductor layer 1252b is formed through sputtering using the aforementioned amorphous material. Meanwhile, the conductor layers 1252a and 1252b may be formed through ALD, CVD, etc., in a similar manner to the manner described above. In the conductor 252b having an amorphous structure, a difference in etching rate between the normal direction and the parallel direction is eliminated. Therefore, the upper surface of the conductor 252b is greater in flatness than that in the crystal structure in which the upper surface is formed into a downwardly convex shape through an etch-back process, as with the first embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic memory device comprising:
a selector body;
a magnetic tunnel junction (MTJ) body provided above the selector body; and
an electrode provided between the selector body and the MTJ body,
wherein the electrode includes a first sub-electrode having a first conductor and a second conductor which is positioned closer to the MTJ body than the first conductor and is in contact with the first conductor,
the first conductor has a crystal structure, and
the second conductor has an amorphous structure.

2. The device according to claim 1, wherein
the second conductor includes an impurity.

3. The device according to claim 2, wherein
the impurity includes at least one element or compound selected from aluminum (Al), silicon (Si), boron (B), and carbon (C).

4. The device according to claim 2, wherein
the first conductor and the second conductor each include at least one element or compound selected from titanium (Ti), tantalum (Ta), tungsten (W), titanium nitride (TiN), tantalum nitride (TaN), and tungsten nitride (WN).

5. The device according to claim 1, wherein
the second conductor is made of an amorphous material.

6. The device according to claim 5, wherein
the first conductor includes at least one element or compound selected from titanium (Ti), tantalum (Ta), tungsten (W), titanium nitride (TiN), tantalum nitride (TaN), and tungsten nitride (WN).

7. The device according to claim 1, wherein
the first sub-electrode includes an impurity, and
the second conductor is higher in a concentration of the impurity than the first conductor.

8. The device according to claim 7, wherein
the impurity includes at least one element or compound selected from aluminum (Al), silicon (Si), boron (B), and carbon (C).

9. The device according to claim 7, wherein
the first sub-electrode includes at least one element or compound selected from titanium (Ti), tantalum (Ta), tungsten (W), titanium nitride (TiN), tantalum nitride (TaN), and tungsten nitride (WN).

10. The device according to claim 1, wherein
the first sub-electrode includes an impurity, and
the first sub-electrode has a gradient of a concentration of the impurity in a direction perpendicular to an upper surface of the first sub-electrode and has a peak in the concentration of the impurity in the second conductor.

11. The device according to claim 1, wherein
the second conductor is smaller in a thickness than the first conductor.

12. The device according to claim 1, wherein
the first sub-electrode has a preferred orientation in a direction perpendicular to an upper surface of the first sub-electrode.

13. The device according to claim 1, wherein
the electrode further includes a second sub-electrode provided between the selector body and the first conductor, and
the second sub-electrode includes at least one element or compound selected from carbon (C) and carbon nitride (CN).

14. The device according to claim 1, wherein
the electrode further includes a third sub-electrode provided between the second conductor and the MTJ body, and
the third sub-electrode includes at least one element or compound selected from titanium (Ti), tantalum (Ta), tungsten (W), titanium nitride (TiN), tantalum nitride (TaN), and tungsten nitride (WN).

15. The device according to claim 1, wherein
the MTJ body includes:
a first ferromagnet;
a second ferromagnet;
a third ferromagnet provided on a side opposite to the first ferromagnet with respect to the second ferromagnet;
a first nonmagnet provided between the first ferromagnet and the second ferromagnet;
a second nonmagnet provided between the second ferromagnet and the third ferromagnet; and
a third nonmagnet provided on a lower surface of the third ferromagnet.

16. A method of manufacturing a magnetic memory device, comprising:
forming a selector layer;
forming a first conductor layer above the selector layer using a first conductive material;
forming a second conductor layer on an upper surface of the first conductor layer using a second conductive material and an impurity;
forming a selector body processed from the selector layer, a first conductor processed from the first conductor layer, and a second conductor processed from the second conductor layer;
forming an insulator on an upper surface of the second conductor and a side surface of each of the selector body, the first conductor, and the second conductor;
exposing the upper surface of the second conductor by removing a part of the insulator and a part of the upper surface of the second conductor; and
forming an MTJ body above the second conductor.

17. The method according to claim 16, wherein
the removing the part of the insulator and the part of the upper surface of the second conductor includes over-etching.

18. A method of manufacturing a magnetic memory device, comprising:
forming a selector layer;
forming a first conductor layer above the selector layer using a first conductive material;
forming a selector body processed from the selector layer and a first conductor processed from the first conductor layer;
forming an insulator on an upper surface of the first conductor and a side surface of each of the selector body and the first conductor;
forming a second conductor in an upper portion of the first conductor by adding an impurity to the first conductor;
exposing an upper surface of the second conductor by removing a part of the insulator and a part of the upper surface of the second conductor; and
forming an MTJ body above the second conductor.

19. The method according to claim 18, wherein
the adding the impurity to the first conductor includes adding the impurity through ion implantation.

20. The method according to claim 18, wherein
the removing the part of the insulator and the part of the upper surface of the second conductor includes over-etching.
